(19) United States
(12) Patent Application Publication
(10) Pub. No.: US 2020/0381319 A1
(43) Pub. Date: Dec. 3, 2020

(54) WAFER CARRIER FOR HANDLING AND TRANSPORTING A WAFER

(71) Applicant: QUALCOMM Incorporated, San Diego, CA (US)

(72) Inventors: Chenjie TANG, San Diego, CA (US); Gengming TAO, San Diego, CA (US); William Clinton Burling PEATMAN, San Diego, CA (US)

(21) Appl. No.: 16/696,507

(22) Filed: Nov. 26, 2019

Related U.S. Application Data
(60) Provisional application No. 62/854,898, filed on May 30, 2019.

(51) Int. Cl. H01L 23/12; H01L 21/677; H01L 21/67; H01L 21/68; H01L 21/66

(52) U.S. Cl. CPC H01L 23/12; H01L 21/67775; H01L 22/32; H01L 21/67144; H01L 21/68; H01L 21/67781

(57) ABSTRACT

A wafer carrier comprising a board, a frame and at least one bolt and nut combination. The board includes at least one vacuum cavity and at least one securing cavity. The frame is coupled to the board. The at least one bolt and nut combination is configured to secure the frame to the board. The board may include one or more metal layers. The frame may include a plurality of scattered frames or a disc shaped frame. The frame may comprise a cavity for the bolt travels through the frame. The wafer carrier may include a wafer located over the board, wherein the wafer is located between the board and the frame.

### CROSS-REFERENCE/CLAIM OF PRIORITY TO RELATED APPLICATION

The present application claims priority to and the benefit of U.S. Provisional Application No. 62/854,898, filed on May 30, 2019, and titled, “WAFER CARRIER FOR HANDLING AND TRANSPORTING A THIN WAFER”, which is hereby expressly incorporated by reference.

### FIELD

Various features relate to a wafer carrier, but more specifically to wafer carriers for handling and transporting a wafer.

### BACKGROUND

A wafer, which is also known as a semiconductor wafer, is a substrate on which integrated devices (e.g., semiconductor dies) are formed. A single wafer may include several hundred integrated devices or several thousand integrated devices. A single wafer may be diced or sliced to form the individual integrated devices (e.g., individual dies). However, before the wafer is diced or sliced, the wafer may be placed on a wafer carrier, so that the wafer can be transported from one place to another.

There is an ongoing need for an improved device and/or an improved method for handling wafers without damaging or breaking the wafer.

### SUMMARY

Various features relate to a wafer carrier, but more specifically to wafer carriers for handling and transporting a wafer.

One example provides a wafer carrier comprising a board, a frame and at least one bolt and nut combination. The board includes at least one vacuum cavity and at least one securing cavity. The frame is coupled to the board. The at least one bolt and nut combination is configured to secure the frame to the board.

Another example provides an apparatus that includes a board, means for securing a wafer and means for locking the wafer. The board includes at least one vacuum cavity and at least one securing cavity. The means for securing the wafer is coupled to the board. The means for locking a wafer is configured to secure the means for securing the wafer to the board.

Another example provides a device for testing a wafer. The device includes a tester, a wafer carrier, at least one probe configured to be electrically coupled to the tester, and a vacuum pump. The wafer carrier is configured to provide support for the wafer. The wafer carrier includes a board comprising: at least one vacuum cavity; and at least one securing cavity. The wafer carrier includes a frame coupled to the board and at least one bolt and nut combination configured to secure the frame to the board. The at least one probe is configured to touch the wafer in order for the tester to test the wafer. The vacuum pump is configured to remove air between a first surface of the wafer carrier and a surface of the wafer. The air is removed through the at least one vacuum cavity of the board.

Another example provides a method for handling a wafer. The method provides a board comprising at least one vacuum cavity and at least one securing cavity. The method provides a wafer over the board. The method performs a vacuum operation on the board to secure the wafer to the board. The method couples a frame to the wafer and the board. The method couples at least one bolt and nut combination to the frame and the board to secure the wafer to the board.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of a device for testing a wafer.

FIG. 2 illustrates an assembly view of an exemplary wafer carrier.

FIG. 3 illustrates a view of an exemplary wafer carrier.

FIG. 4 illustrates a side profile view of an exemplary wafer carrier.

FIG. 5 illustrates a top plan view of an exemplary wafer carrier.

FIG. 6 illustrates an assembly view of a wafer carrier that includes a frame that has a disc shape.

FIG. 7 illustrates a view of a wafer carrier that includes a frame that has a disc shape.

FIG. 8 illustrates a side profile view of a wafer carrier that includes a frame that has a disc shape.

FIG. 9 illustrates a top plan view of a wafer carrier that includes a frame that has a disc shape.

FIG. 10 (comprising FIGS. 10A-10B) illustrates an exemplary sequence for handling a wafer.

FIG. 11 illustrates an exemplary flow diagram of a method for handling a wafer.

FIG. 12 illustrates a profile view of a device for testing a wafer, where the device comprises a wafer carrier.

FIG. 13 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a wafer carrier comprising a board, a frame and at least one bolt and nut combination. The board includes at least one vacuum cavity and at least one securing cavity. The frame is coupled to the board. The at least one bolt and nut combination is configured to secure the frame to the board. The board may include one or more metal layers. The frame may include a plurality of scattered frames or a disc shaped frame. The frame may include a cavity that is configured for the bolt to travel through the frame. The wafer carrier may include a wafer (e.g., semiconductor wafer) located over the board. The wafer is located between the board and the frame. The wafer may include a plurality of integrated devices (e.g., dies, semiconductor dies, integrated passive devices (IPDs)). The wafer carrier may be configured to securely handle a wafer, which reduces the likelihood of the wafer (e.g., thin wafer) from breaking during handling and/or transporting of the wafer.

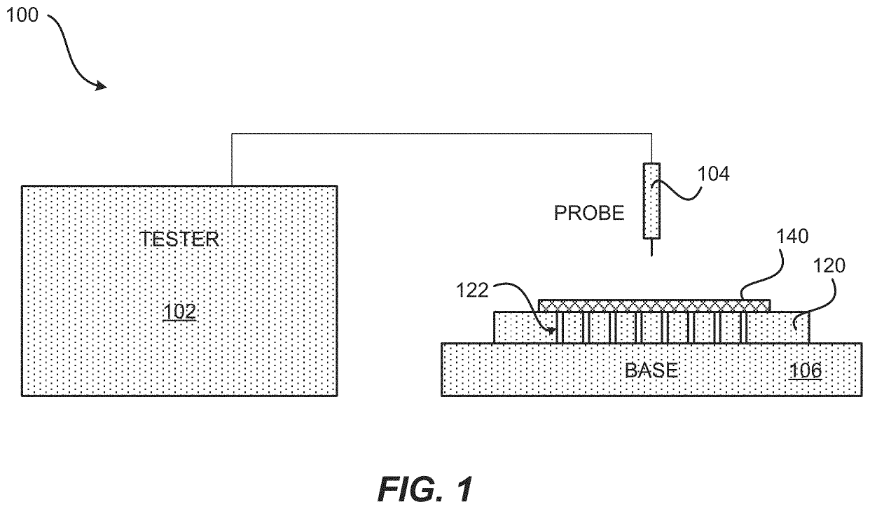

FIG. 1 illustrates a device 100 configured for testing a wafer. The device 100 may be a wafer testing device. The device 100 may include a single device or a system that includes several components on different devices. The device 100 includes a tester 102, at least one probe 104, a base 106, and a wafer carrier 120. The wafer carrier 120 includes a plurality of cavities 122.

A wafer 140 is positioned over a first surface (e.g., top surface) of the wafer carrier 120. The wafer carrier 120 may include a board. The wafer carrier 120 is located over the base 106. The base 106 may be physically part of the tester 102. The base 106 may be a platform or a structure on which the wafer carrier 120 is positioned over. The base 106 may include other components, such as a vacuum device (e.g., vacuum pump) for performing a vacuum operation. A vacuum operation may be an operation that removes air (or any gases) between the wafer 140 and the wafer carrier 120. The air may be removed through the plurality of cavities 122 of the wafer carrier 120. Removing the air through the vacuum operation may cause the wafer 140 to be securely coupled to the wafer carrier 120. This causes the wafer 140 to remain in a fixed position while the testing of the wafer 140 is performed. The vacuum operation may include maintaining a vacuum state (or near vacuum state) between the wafer 140 and the wafer carrier 120. A vacuum state (or near vacuum state) may be a state where the air pressure between the wafer 140 and the wafer carrier 120 is less than the air pressure in the environment that surrounds the wafer 140 and the wafer carrier 120.

The tester 102 may include a processor and a memory. The tester 102 is configured to be electrically coupled to one or more probes 104. During the testing of the wafer 140, one or more probes 104 may connect (e.g., touch) to input/outputs of dies on the wafer 140. The tester 102 may send and receive signals to and from the integrated devices (e.g., dies) over the wafer 140 though one or more probes 104 to test that the integrated devices are functional and working properly. The tester 102 may move one or more probes 104 to test several integrated devices. Since the integrated devices are located in a pre-defined matter on the wafer 140, several integrated devices may be concurrently tested through the use of several probes. In some implementations, the wafer 140 may be heated (through a heating mechanism) in order to test how the integrated device(s) perform under heat stress.

In at least some implementations, as long as the vacuum is operational on the wafer carrier 120 (and/or there is a vacuum state between the wafer carrier 120 and the wafer 140), the wafer 140 will remain relatively fixed, enabling the tester 102 to perform testing on the wafer 140 through the at least one probe 104. However, using the vacuum is not practical when handling and transporting the wafer to and from different locations. In addition to the vacuum, further modifications to the wafer carrier may be made to improve how a wafer is handled and securely coupled to a wafer carrier.

### Exemplary Wafer Carrier

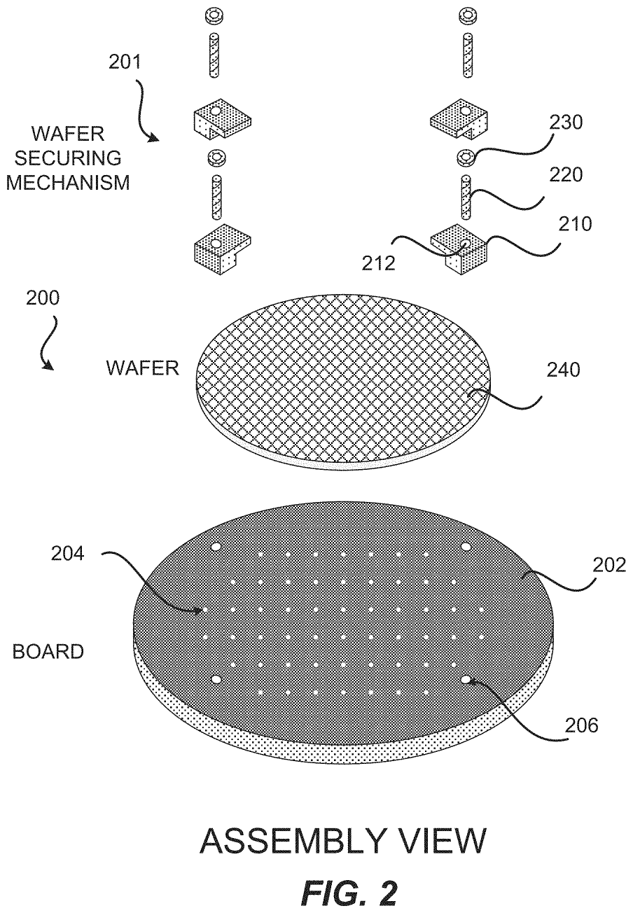

FIG. 2 illustrates an assembly view of a wafer carrier 200 that in configured for handling and transporting a wafer (e.g., thin wafer). The wafer carrier 200 includes a board 202 and a wafer securing mechanism 201. The wafer carrier 200 is configured in such a way that the wafer 240 is positioned between the board 202 and the wafer securing mechanism 201. The wafer securing mechanism 201 may include a wafer securing structure.

The board 202 includes a plurality of vacuum cavities 204 and a plurality of securing cavities 206. The board 202 may be made of single piece of material (e.g., metal, aluminum, copper) or may include several layers (e.g., several metal layers). In some implementations, the board 202 may include a composite material. Different implementations may use different materials for the board 202. The board 202 is shown with a plurality of vacuum cavities 204. However, the board 202 may include one or more vacuum cavities (e.g., at least one vacuum cavity).

The plurality of vacuum cavities 204 may travel through the thickness of the board 202. The plurality of vacuum cavities 204 is configured to allow air to be vacuumed away from the wafer that is positioned over the board 202. The plurality of securing cavities 206 is configured to allow a bolt (or other coupling device, such as a screw) to travel in and through the board 202. In some implementations, the bolt may travel partially through the board 202. The plurality of securing cavities 206 may be threaded. The plurality of vacuum cavities 204 and the plurality of securing cavities 206 may have different shapes. In some implementations, the plurality of vacuum cavities 204 and/or the plurality of securing cavities 206 are holes (e.g., circular shape). Different implementations may have different numbers of vacuum cavities 204 and/or different numbers of securing cavities 206. Thus, for example, the board 202 may include at least one vacuum cavity and at least one securing cavity. In addition, different implementations may position the plurality of vacuum cavities 204 and/or the plurality of securing cavities 206 in different parts of the board 202. One or more securing cavities from the plurality of securing cavities 206 may travel partially or entirely through the board 202.

One or more of vacuum cavity from the plurality of vacuum cavities 204 may have the same or different diameters and/or width. In some implementations, one or more vacuum cavity from the plurality of vacuum cavities 204 may have a diameter of approximately 150 micrometers (μm) or less, through the entirety of the board 202. In some implementations, one or more of vacuum cavity from the plurality of vacuum cavities 204 may have a variable diameter. That is, as the vacuum cavity travels through the board 202, the vacuum cavity may have different diameters. In some implementations, the board 202 may have a first surface (e.g., top surface, front surface, surface configured to face wafer) and a second surface (e.g., bottom surface, back surface, surface configured to face away from a wafer), and one or more vacuum cavities may have a first diameter at the first surface of the board 202, and a second diameter at the second surface of the board 202. For example, one or more cavities may have (i) a first diameter of approximately 150 micrometers (μm) or less, at the first surface of the board 202, and (ii) a second diameter of approximately 500 micrometers (μm) or greater (e.g., 1 millimeter), at the second surface of the board 202. In some implementations, the diameter of the vacuum cavities has to be small enough so that a probe for a tester does not protrude in the vacuum cavities, which can cause the probe to be damaged. The use of the term diameter for the plurality of vacuum cavities 204 may refer to the width of a vacuum cavity from the plurality of vacuum cavities 204.

The wafer securing mechanism 201 (e.g., means for securing the wafer) includes a frame 210, a bolt 220 and a nut 230. The frame 210 includes a cavity 212. The frame 210 has an L-shape. However, the frame 210 may have different shapes (e.g. rectangle, trapezoid). The frame 210 may be a unibody frame or may be made of several components and/or materials. The bolt 220 and the nut 230 (e.g., bolt and nut combination) are used to couple the frame 210 to the board 202. The bolt 220 and the nut 230 may be a locking mechanism (e.g., means for locking the wafer). As shown in FIG. 2, there are four sets of frames 210 and four sets of bolt and nut combinations. However, different implementations may use different numbers of frames 210 and different numbers of bolt and nut combinations. Different implementations may use materials (e.g., one or more metal layers, copper) for the frame 210, the bolt 220 and/or the nut 230 that are similar or different than the board 202.

It is noted that one or more nut 230 may be located over the board 202 and/or embedded in the board 202 through one or more cavities (e.g., securing cavities). In some implementations, the nut 230 may be located over the first surface or the second surface of the board 202. In some implementations, the nut 230 may be located in a cavity of the first surface of the board 202 and/or a cavity of the second surface of the board 202. It is noted that one or more nut 230 may be located over the frame 210 and/or embedded in the frame 210 through one or more cavities. In some implementations, the nut 230 may be located in a cavity of the frame 210.

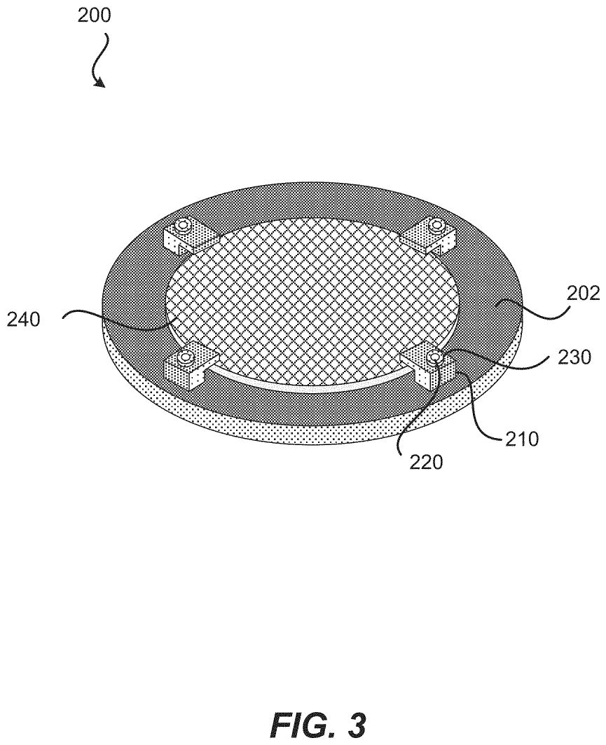

FIG. 3 illustrates the wafer 240 located over the wafer carrier 200, The wafer 240 may be coupled to the wafer carrier 200. The wafer securing mechanism 201 (which includes the frame 210, the bolt 220 and the nut 230) securely couples the wafer 240 to the board 202, so that the wafer 240 can be safely handled and securely transported. Through the tightening of the bolt 220 and the nut 230, the frame 210 applies a pressure (e.g., force) that pushes the wafer 240 against the board 202 thereby holding the wafer 240 securely in place, even if there is no vacuum between the wafer 240 and the board 202. Several frames 210 and bolt and nut combinations may be used to reduce the force on the wafer 240, and thus reducing the likelihood of breaking or damaging the wafer 240.

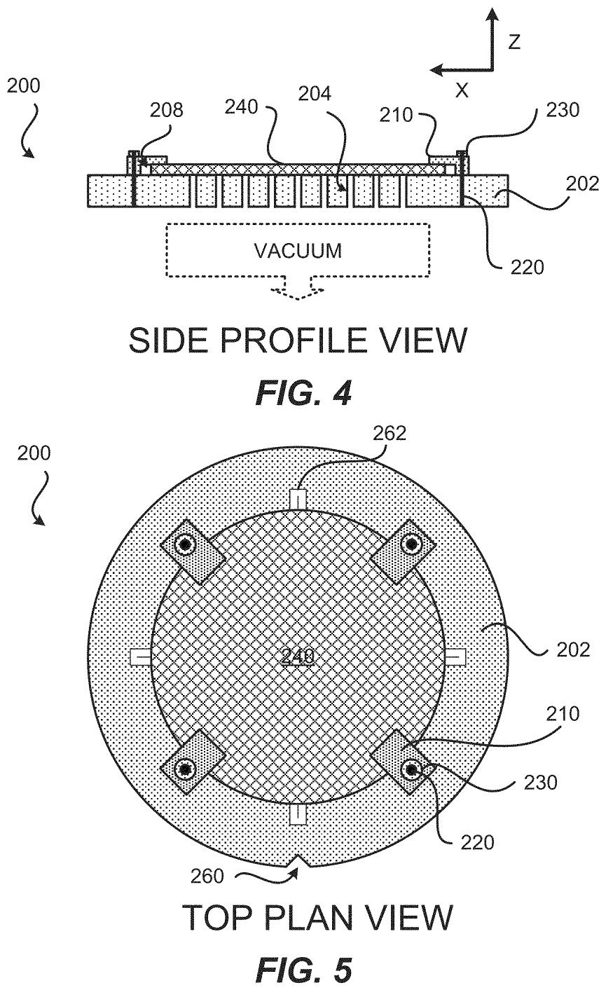

FIG. 4 illustrates a side profile view of the wafer carrier 200 that includes the wafer 240. As shown in FIG. 4, when a vacuum operation is performed, air may be moved away (e.g., removed) from the wafer 240 through the plurality of vacuum cavities 204. A vacuum operation may include removing at least some air (or any gases) between the wafer 240 and the board 202, such that the air pressure around the wafer 240 and the board 202 is greater than the air pressure between the wafer 240 and the board 202. To secure the wafer 240 to the board 202, the frame 210 is coupled to the board 202 and the wafer 240. The bolt 220 is inserted in the cavity 212 of the frame 210, and the securing cavity 206 of the board 202. In some implementations, one or both of the cavity 212 and the securing cavity 206 may be threaded. The nut 230 may be coupled to the bolt 220 to secure the frame 210 and the wafer 240 to the board 202.

FIG. 4 illustrates a gap 208 (e.g., lateral gap, lateral spacing) between a side surface (e.g., side wall of the wafer 240) and a side surface of the frame 210. The gap 208 is there to allow the wafer 240 to expand (e.g., laterally expand, expand along surface of the board 202). In some implementations, testing a wafer 240 may include testing the wafer under different temperatures conditions. Under hotter conditions, the wafer 240 may expand (e.g., laterally expand, expand along surface of the board). The shape and/or location of the frame 210 allows the wafer 240 to expand if and when the wafer 240 is subjected to higher temperatures or conditions.

FIG. 5 illustrates a top plan view of the wafer carrier 200. The wafer carrier 200 includes an alignment notch 260 and at least one alignment marker 262. The alignment notch 260 may be part of the board 202. The alignment notch 260 may be used to properly align the board 202 on a base (e.g., 106) of a tester. Both the alignment notch 260 and the alignment marker 262 may be used to properly align the wafer 240 on the board 202. The wafer 240 may include a corresponding alignment notch, which may be used to align to the alignment notch 260. As shown in FIG. 5, there are several alignment markers 262. In some implementations, the board 202 may include several alignment notches 260. In some implementations, the alignment notch 260 may appear in a different location on the board 202 (e.g., halfway between south and east).

### Exemplary Wafer Carrier Comprising a Frame Having a Disc Shape

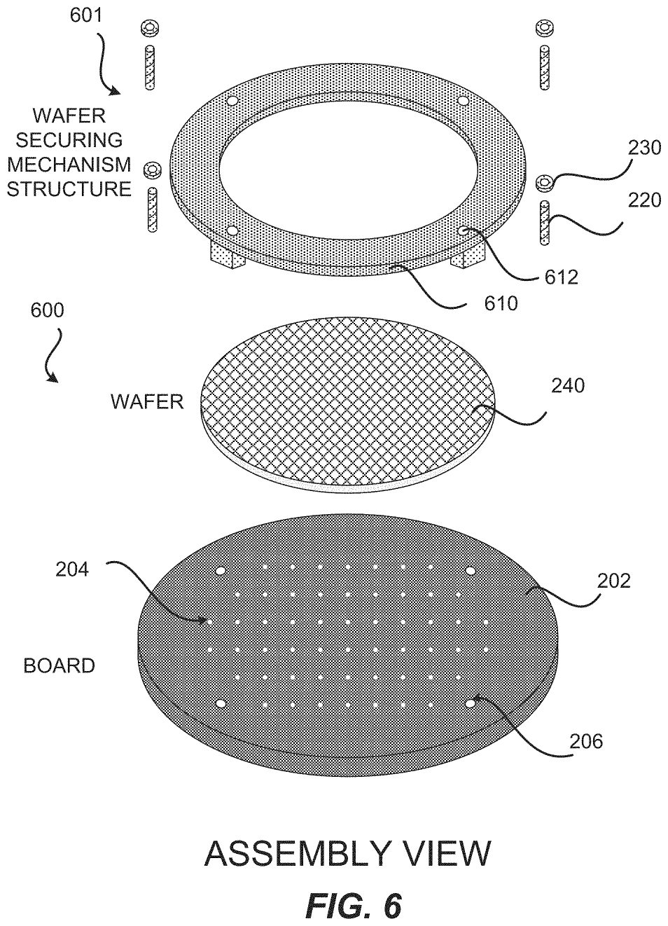

FIG. 6 illustrates an assembly view of a wafer carrier 600 that is configured for handling and transporting a wafer (e.g., thin wafer). The wafer carrier 600 includes a board 202 and a wafer securing mechanism 601. The wafer carrier 600 is configured in such a way that the wafer 240 is positioned between the board 202 and the wafer securing mechanism 601. The wafer carrier 600 may be similar to the wafer carrier 200. The wafer securing mechanism 601 may be similar to the wafer securing mechanism 201. However, as will be further described below, the wafer securing mechanism 601 includes a frame that has a different shape than the frame 210 of the wafer carrier 200.

The board 202 includes a plurality of vacuum cavities 204 and a plurality of securing cavities 206. The board 202 may be made of single piece of material (e.g., metal, copper) or may include several layers (e.g., several metal layers). In some implementations, the board 202 may include a composite material. Different implementations may use different materials for the board 202.

The plurality of vacuum cavities 204 may travel through the thickness of the board 202. The plurality of vacuum cavities 204 is configured to allow air to be vacuumed away from a wafer that is positioned over the board 202. The plurality of securing cavities 206 is configured to allow a bolt (or other coupling device, such as a screw) to travel in and through the board 202. The plurality of securing cavities 206 may be threaded. The plurality of vacuum cavities 204 and the plurality of securing cavities 206 may have different shapes. In some implementations, the plurality of vacuum cavities 204 and/or the plurality of securing cavities are holes (e.g., circular shape). Different implementations may have different numbers of vacuum cavities and/or different numbers of securing cavities 206. In addition, different implementations may position the plurality of vacuum cavities 204 and/or the plurality of securing cavities in different parts of the board 202.

The wafer securing mechanism 601 (e.g., means for securing the wafer) includes a frame 610, a bolt 220 and a nut 230. The frame 610 includes a cavity 612. The frame 610 includes a disc shaped frame (e.g., donut shaped frame). However, the frame 610 may have different shapes. The frame 610 may be a unibody frame or may be made of several components and/or materials. The size and shape of the frame 610 provides a more secure coupling of the wafer 240 to the board 202. In addition, the increase area size of the frame 610 relative to the frame 210, helps reduce the pressure per area (e.g., force per area) on the wafer 240, thereby reducing the likelihood of the wafer 240 to break or be damaged. The bolt 220 and the nut 230 (e.g., bolt and nut combination) are used to couple the frame 610 to the board 202. The bolt 220 and the nut 230 may be a locking mechanism (e.g., means for locking the wafer). Different implementations may use different numbers of frames 610 and bolt and nut combinations. Different implementations may use materials (e.g., one or more metal layers, copper) for the frame 610, the bolt 220 and/or the nut 230 that are similar or different than the board 202.

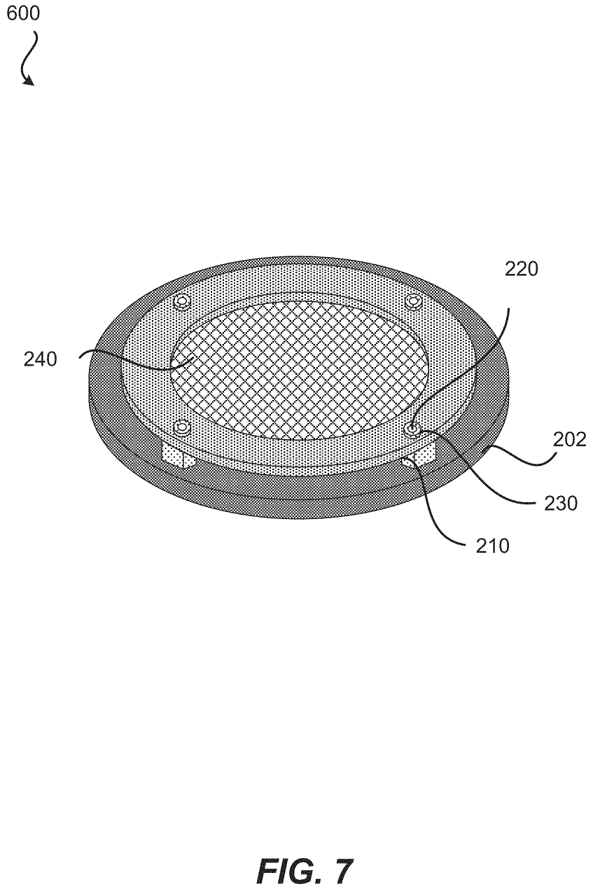

FIG. 7 illustrates the wafer carrier 600 that includes the wafer 240. As shown in FIG. 7, the wafer securing mechanism 601 (which includes the frame 610, the bolt 220 and the nut 230) a securely coupled the wafer 240 to the board 202, so that the wafer 240 can be safely handled and securely transported. Through the tightening of the bolt 220 and the nut 230, the frame 610 applies a pressure (e.g., force) that pushes the wafer 240 against the board 202 thereby holding the wafer 240 securely in place, even if there is no vacuum operation (and/or vacuum state) on the wafer 240 and/or the board 202.

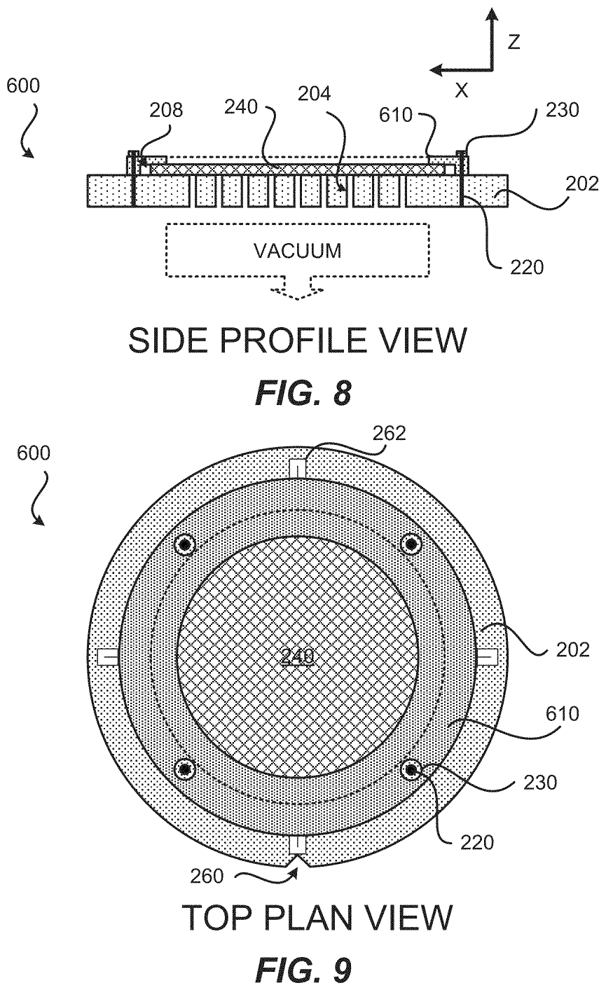

FIG. 8 illustrates a side profile view of the wafer carrier 600 that includes the wafer 240. As shown in FIG. 8, when a vacuum operation is performed, air (or any gases) may be moved away (e.g., removed) between the wafer 240 and the board 202, through the plurality of vacuum cavities 204. To secure the wafer 240 to the board 202, the frame 610 is coupled to the board 202 and the wafer 240. The bolt 220 is inserted in the cavity 612 of the frame 610, and the securing cavity 206 of the board. In some implementations, one or both of the cavity 612 and the securing cavity 206 may be threaded. The nut 230 may be coupled to the bolt 220 to secure the frame 610 and the wafer 240 to the board 202.

FIG. 8 illustrates a gap 208 (e.g., lateral gap, lateral spacing) between a side surface (e.g., side wall of the wafer 240) and a side surface of the frame 610. The gap 208 is there to allow the wafer 240 to expand. In some implementations, testing a wafer 240 may include testing the wafer under different temperatures conditions. Under hotter conditions, the wafer 240 may expand (e.g., laterally expand). The shape and/or location of the frame 610 allows the wafer 240 to expand if and when the wafer 240 is subjected to higher temperatures or conditions.

FIG. 9 illustrates a top plan view of the wafer carrier 600. The wafer carrier 600 includes an alignment notch 260 and at least one alignment marker 262. The alignment notch 260 may be part of the board 202. The alignment notch 260 may be used to properly align the board 202 on a base (e.g., 106) of a tester. Both the alignment notch 260 and the alignment marker 262 may be used to properly align the wafer 240 on the board 202. The wafer 240 may include a corresponding alignment notch, which may be used to align to the alignment notch 260. As shown in FIG. 9, there are several alignment markers 262. In some implementations, the board 202 may include several alignment notches 260. In some implementations, the alignment notch 260 may appeal in a different location on the board 202 (e.g., halfway between south and east).

### Exemplary Sequence for Using a Wafer Carrier for Handling and Transporting a Wafer

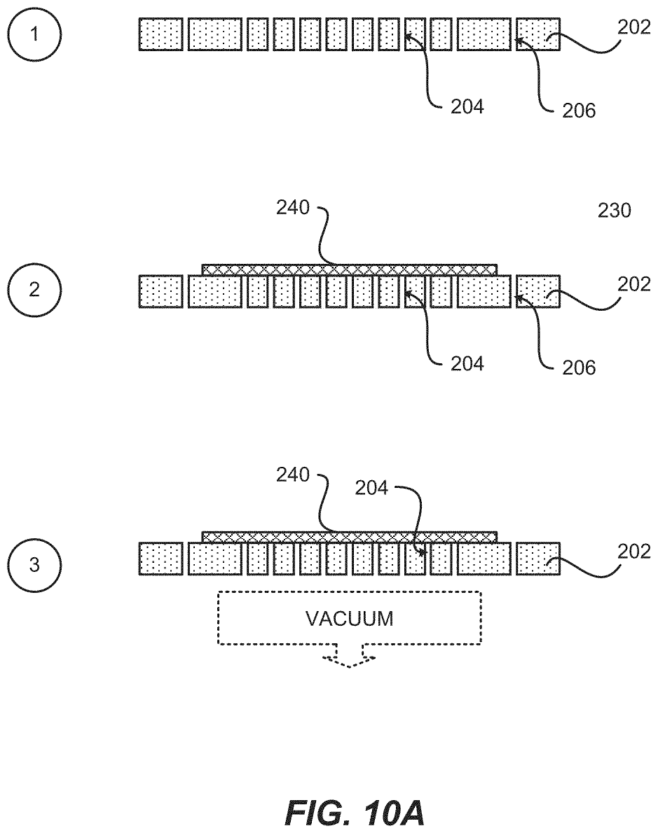

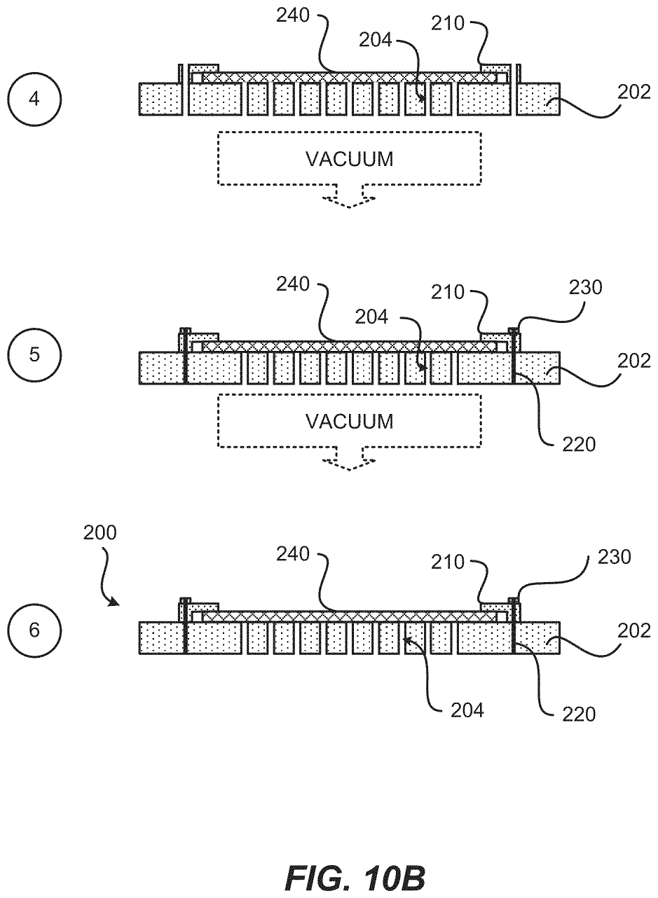

FIG. 10 (which includes FIGS. 10A-10B) illustrates an exemplary sequence for using a wafer carrier for handling and transporting a wafer. In some implementations, the sequence of FIGS. 10A-10B may be wafer carrier of FIG. 2, or any of the carriers described in the disclosure.

It should be noted that the sequence of FIGS. 10A-10B may combine one or more stages in order to simplify and/or clarify the sequence for handling and/or transporting a wafer. In some implementations, the order of the processes may be changed or modified. In some implementations, one or more of processes may be replaced or substituted without departing from the spirit of the disclosure.

Stage 1, as shown in FIG. 10A, illustrates a state after a board 202 that includes a plurality of vacuum cavities 204 and a plurality of securing cavities 206, is provided. The board 202 may include one or more layers (e.g., one or more metal layers). Different implementations may use a board 202 with different sizes. In some implementations, the board 202 may have a diameter of at least about 8 inches.

Stage 2 illustrates a state after the wafer 240 is provided over a first surface (e.g., top surface) of the board 202. The wafer 240 may have different sizes. In some implementations, the wafer 240 may have a diameter that is approximately 6 inches. In some implementations, the wafer 240 may include several integrated devices (e.g., dies). In some implementations, the wafer 240 is a wafer after a front end of line (FEOL) processing or part of a FEOL processing has been performed. The FEOL processing may form transistors on the substrate (e.g., gallium arsenide or silicon). In some implementations, the wafer 240 is a wafer after back end of line (BEOL) processing or part of BEOL processing has been performed.

Stage 3 illustrates a state after a vacuum operation is performed to remove as much air (or any gases) as possible between the board 202 and the wafer 240. The vacuum operation removes the air through the plurality of vacuum cavities 204 of the board 202. The vacuum operation helps securely hold the wafer 240 to the board 202.

Stage 4, as shown in FIG. 10B, illustrates a state after at least one frame 210 is provided over the wafer 240 and the board 202. In some implementations, the frame 610 may be provided over the wafer 240 and the board 202. The vacuum operation may still be operating during this state.

Stage 5 illustrates a state after the bolt 220 and the nut 230 (e.g., bolt and nut combination) are used to secure the frame 210 to the board 202, such that the frame 210 securely holds the wafer 240 to the board 202. The vacuum operation may still be operating during this state.

Stage 6, illustrates a state after the vacuum operation ceases to operate on the board 202, thus allowing the board 202 and the wafer 240 to be transported to a different location.

### Exemplary Flow Diagram of a Method for Using a Wafer Carrier for Handling and Transporting a Wafer

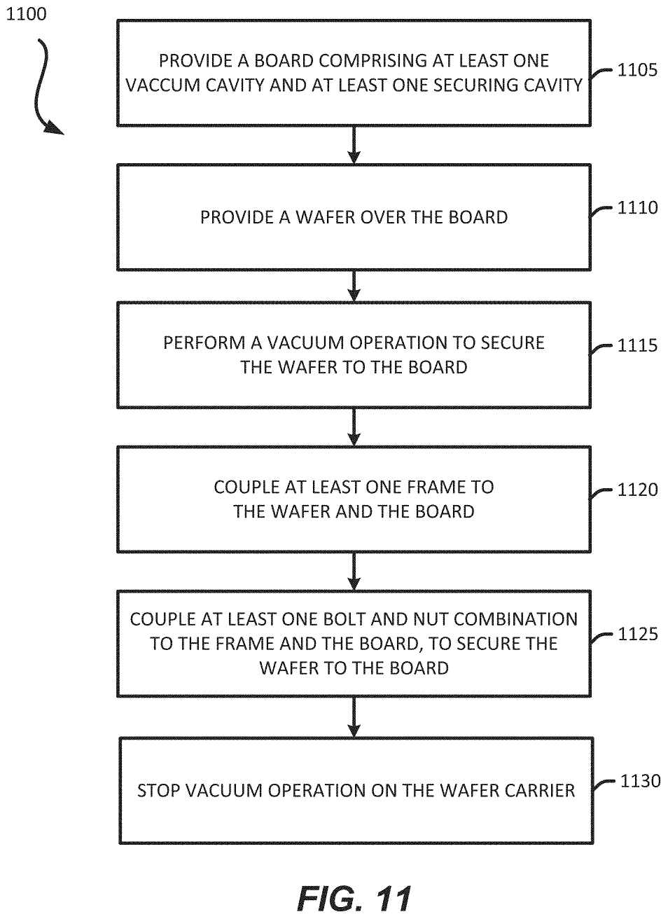

FIG. 11 illustrates an exemplary flow diagram of a method 1100 for using a wafer carrier for handling and transporting a wafer. In some implementations, the method 1100 of FIG. 11 may be used to handle and transport the wafer 240. However, the method 1100 may be used to handle or transport any wafers.

It should be noted that the sequence of FIG. 11 may combine one or more processes in order to simplify and/or clarify the method for using a wafer carrier. In some implementations, the order of the processes may be changed or modified.

The method provides (at 1105) a board (e.g., 202) that includes at least one vacuum cavity (e.g., plurality of vacuum cavities 204) and at least one securing cavity (e.g., plurality of securing cavities 206). The board 202 may include one or more layers (e.g., one or more metal layers). Different implementations may use a board 202 with different sizes and/or shapes. In some implementations, the board 202 may have a diameter of at least approximately 8 inches.

The method provides (at 1110) a wafer (e.g., 240) over a first surface (e.g., top surface) of the board 202. The wafer 240 may have different sizes. In some implementations, the wafer 240 may have a diameter that is approximately 6 inches. In some implementations, the wafer 240 may include several integrated devices (e.g., dies, IPDs). In some implementations, the wafer 240 is a wafer after a front end of line (FEOL) processing or part of a FEOL processing has been performed. The FEOL processing may form transistors over a substrate (e.g., gallium arsenide or silicon) that is part of the wafer. In some implementations, the wafer 240 is a wafer after back end of line (BEOL) processing or part of BEOL processing has been performed.

The method performs (at 1115) a vacuum operation to remove air (and/or any gases) between the board 202 and the wafer 240. The vacuum operation removes the air through the plurality of vacuum cavities 204 of the board 202. The vacuum operation helps securely hold the wafer 240 to the board 202. In some implementations, the vacuum operation may not remove all of the air between the board 202 and the wafer 240, but removes enough air between the board 202 and the wafer 240 to secure the wafer 240 to the board 202.

The method couples (at 1120) at least one frame (e.g., 210, 610) to the wafer 240 and the board 202. In such an instance, the method may provide at least one frame over the wafer 240 and the board 202. The vacuum operation may still be operating during this state.

The method couples (at 1125) at least one bolt and nut combination (e.g., at least one bolt (e.g., 220) and at least one nut (e.g., 230)) to the frame (e.g., 210, 610) and the board (e.g., 202), to secure the frame to the board 202, such that the frame securely holds the wafer 240 to the board 202. The vacuum operation may still be operating during this state.

The method ceases (at 1130) to operate the vacuum operation on the board 202, thus allowing the frame (e.g., 210, 610), the board 202 and the wafer 240 to be transported to a different location (e.g., to/from a testing device).

### Exemplary Wafer Testing Device

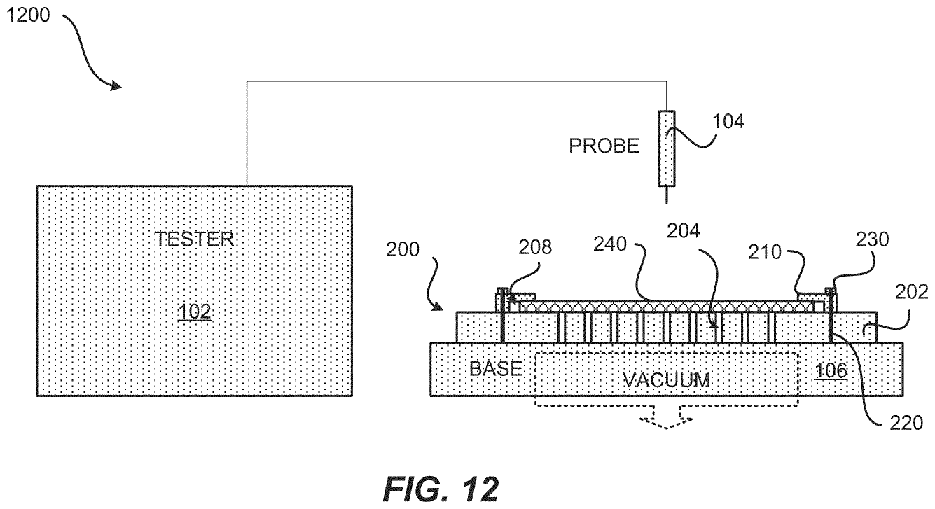

FIG. 12 illustrates a device 1200 configured for testing a wafer. The device 1200 may be a wafer testing device. The device 1200 may be similar to the device 100. The device 1200 may be configured to accommodate a wafer carrier that includes a wafer securing mechanism (e.g., 201, 601) for securing a wafer to a board. Examples of a wafer carrier include the wafer carrier 200 and the wafer carrier 600. The device 1200 of FIG. 12 will be described in the context of using the wafer carrier 200. However, the device 1200 may be used with the wafer carrier 600 and/or any other wafer carriers.

The device 1200 may include a single device or a system that includes several components on different devices. The device 1200 includes the tester 102, at least one probe 104, the base 106, and the wafer carrier 200.

As described above in at least FIG. 2, the wafer carrier 200 includes a board 202 and a wafer securing mechanism 201. The wafer carrier 200 is configured to provide support for the wafer 240. The wafer carrier 200 is configured in such a way that the wafer 240 is positioned between the board 202 and the wafer securing mechanism 201. The wafer securing mechanism 201 (e.g., means for securing the wafer) includes the frame 210, the bolt 220 and the nut 230. The frame 210 includes a cavity 212. The board 202 includes a plurality of vacuum cavities 204.

The wafer 240 is positioned over a first surface (e.g., top surface) of the wafer carrier 200 (e.g., over a first surface of the board 202). The wafer carrier 200 is located over the base 106. The base 106 may be physically part of the tester 102. The base 106 may be a platform or a structure on which the wafer carrier 200 is positioned over. The base 106 may be configured to accommodate the wafer carrier 200, including the bolt 220, for example. The base 106 may include cavities and/or notches (e.g., over a surface of the base 106) that the bolt 220 can couple to. Thus, in some implementations, it may not be necessary to remove the bolt 220 from the board 202, when the wafer 240 is being tested. The base 106 may include other components, such as a vacuum device (e.g., vacuum pump) configured for performing a vacuum operation. A vacuum operation may be an operation that removes air (and/or any gases) between the wafer 240 and a surface of the wafer carrier 200. The air may be removed through the plurality of vacuum cavities 204 of the board 202. Removing the air (or as much air as possible) through the vacuum operation may cause the wafer 240 to be securely coupled to the board 202 of the wafer carrier 200. A vacuum operation may include removing air and/or maintaining a vacuum state. Thus, for example, when enough air has been removed between the board 202 and the wafer 240, the vacuum operation may stop pumping air out, but the board 202 and the wafer 240 may be considered in a vacuum state (or near vacuum state) because there is less air between the board 202 and the wafer 240, than air surrounding the board and the wafer 240. A vacuum state may be considered part of a vacuum operation. The vacuum operation and/or the vacuum state, may cause the wafer 240 to remain in a fixed position while the testing of the wafer 240 is performed. In some implementations, the vacuum operation may not be necessary to securely couple the wafer carrier 200 to the base 106. For example, the bolt 220 may be coupled to cavities and/or notches in the base 106, which may help prevent the wafer carrier 200 and the wafer 240 from laterally moving, relative to the base 106.

Once the wafer carrier 200 and/or the wafer 240 is secure over the base 106 (e.g., through the vacuum operation, vacuum state and/or coupling of a bolt to the base 106), the testing of the wafer 240 may be performed.

As mentioned above, the tester 102 may include a processor and a memory. The tester 102 is electrically coupled to one or more probes 104. During the testing of the wafer 240, one or more probes 104 may connect (e.g., touch) to input/outputs of integrated devices (e.g., dies) over the wafer 240. The tester 102 may send and receive signals to and from the integrated devices over the wafer 240 though one or more probes 104 to test that the integrated devices are functional and working properly. The tester 102 may move the one or more probes 104 to test several integrated devices. Since the integrated devices are located in a pre-defined matter on the wafer 240, several integrated devices may be concurrently tested through the use of several probes. In some implementations, the wafer 240 may be heated (through a heating mechanism) in order to test how the integrated device(s) perform under heat stress.

### Exemplary Electronic Devices

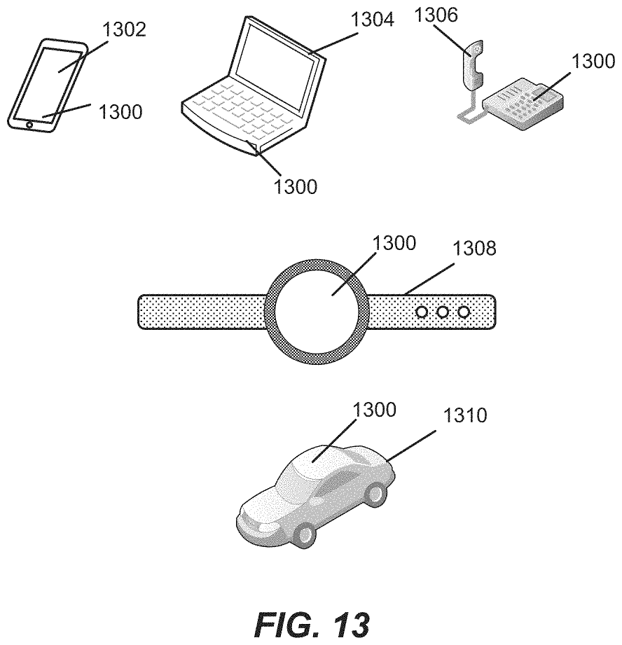

FIG. 13 illustrates various electronic devices that may be integrated with any of the aforementioned integrated device, integrated circuit (IC) package, integrated circuit (IC) device, semiconductor device, integrated circuit, die, interposer, package, package-on-package (PoP), System in Package (SiP), or System on Chip (SoC). The integrated device, integrated circuit (IC) package, integrated circuit (IC) device, semiconductor device, integrated circuit, die, interposer, package, package-on-package (PoP), System in Package (SiP), System on Chip (SoC), and/or may be formed from a wafer that is diced or singulated. For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-9, 10A-10B, and/or 11-13 may be rearranged and/or combined into a single component, process, feature or function or embodied in several components, processes, or functions. Additional elements, components, processes, and/or functions may also be added without departing from the disclosure. It should also be noted FIGS. 2-9, 10A-10B, and/or 11-13 and its corresponding description in the present disclosure is not limited to dies and/or ICs. In some implementations, FIGS. 2-9, 10A-10B, and/or 11-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, carriers, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation.

The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., a data signal, ground or power). An interconnect may be part of a circuit. An interconnect may include more than one element or component. An interconnect may be defined by one or more interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A wafer carrier comprising:
a board comprising:
at least one vacuum cavity; and
at least one securing cavity;
a frame coupled to the board; and
at least one bolt and nut combination configured to secure the frame to the board.

2. The wafer carrier of claim 1, wherein the board comprises one or more metal layers.

3. The wafer carrier of claim 1, wherein the frame comprises a plurality of scattered frames or a disc shaped frame.

4. The wafer carrier of claim 1,
wherein the frame comprises a cavity configured for the bolt to travel through the frame, and
wherein the bolt is configured to travel in at least one securing cavity of the board.

5. The wafer carrier of claim 1, wherein the board is configured to couple to a wafer such that the wafer is located between the board and the frame.

6. The wafer carrier of claim 5, wherein the bolt and nut combination is configured to secure the wafer to the board.

7. The wafer carrier of claim 5, wherein the frame is configured to couple to the wafer such that there is a lateral gap between a side portion of the frame and a side portion of the wafer, to allow the wafer to expand when the wafer is subject to heat.

8. The wafer carrier of claim 1, wherein the board further comprises an alignment notch.

9. The wafer carrier of claim 1, wherein the board further comprises an alignment marker.

10. The wafer carrier of claim 1, wherein the at least one vacuum cavity comprises a diameter of approximately 150 micrometers or less.

11. An apparatus comprising:
a board comprising:
at least one vacuum cavity; and
at least one securing cavity;
means for securing a wafer to the board; and
means for locking the wafer to the board.

12. The apparatus of claim 11, wherein the board comprises one or more metal layers.

13. The apparatus of claim 11, wherein the means for securing a wafer comprises a plurality of scattered frames or a disc shaped frame.

14. The apparatus of claim 11,
wherein the means for securing a wafer comprises a cavity configured for the means for locking to travel through the means for securing a wafer; and
wherein the means for locking the wafer is configured to travel in at least one securing cavity of the board.

15. The apparatus of claim 11, wherein the board is configured to couple to a wafer such that the wafer is located between the board and the means for securing a wafer.

16. The apparatus of claim 15, wherein the means for locking the wafer is configured to secure the wafer to the board.

17. The apparatus of claim 15, wherein the means for securing a wafer is configured to couple to the wafer such that there is a lateral gap between a side portion of the means for securing a wafer and a side portion of the wafer, to allow the wafer to expand when the wafer is subject to heat.

18. The apparatus of claim 11, wherein the board further comprises an alignment notch.

19. The apparatus of claim 11, wherein the board further comprises an alignment marker.

20. The apparatus of claim 11, wherein the board is configured to couple to a wafer comprising a plurality of integrated devices.

21. A device for testing a wafer, comprising:
a tester;
a wafer carrier configured to provide support for the wafer, the wafer carrier comprising:
a board comprising:
at least one vacuum cavity; and
at least one securing cavity;
a frame coupled to the board; and
at least one bolt and nut combination configured to secure the frame to the board;
at least one probe configured to be electrically coupled to the tester, wherein the at least one probe is configured to touch the wafer in order for the tester to test the wafer; and
a vacuum pump configured to remove air between a first surface of the wafer carrier and a surface of the wafer, wherein the air is removed through the at least one vacuum cavity of the board.

22. The device of claim 21, wherein the board comprises one or more metal layers.

23. The device of claim 21, wherein the frame comprises a plurality of scattered frames or a disc shaped frame.

24. The device of claim 21,
wherein the frame comprises a cavity configured for the bolt to travel through the frame, and
wherein the bolt is configured to travel in at least one securing cavity of the board.

25. The device of claim 21, wherein the board is configured to couple to a wafer such that the wafer is located between the board and the frame.

26. The device of claim 25, wherein the bolt and nut combination is configured to secure the wafer to the board.

27. A method for handling a wafer, comprising:
providing a board comprising:
at least one vacuum cavity; and
at least one securing cavity;
providing a wafer over the board;
performing a vacuum operation on the board to secure the wafer to the board;
coupling a frame to the wafer and the board; and
coupling at least one bolt and nut combination to the frame and the board to secure the wafer to the board.

28. The method of claim 27, further comprising stopping the vacuum operation, after coupling the at least one bolt and nut combination to the frame.
